(19) United States
(12) Patent Application Publication
(10) Pub. No.: US 2025/0259859 A1
(43) Pub. Date: Aug. 14, 2025

(54) METHOD FOR MANUFACTURING SEMICONDUCTOR PACKAGE

(71) Applicant: Resonac Corporation, Minato-ku, Tokyo (JP)

(72) Inventors: Yuki IMAZU, Minato-ku, Tokyo (JP); Keiichi HATAKEYAMA, Minato-ku, Tokyo (JP); Motoo AOYAMA, Minato-ku, Tokyo (JP); Dongchul KANG, Minato-ku, Tokyo (JP); Sadaaki KATO, Minato-ku, Tokyo (JP); Keiko UENO, Minato-ku, Tokyo (JP); Kazue HIRANO, Minato-ku, Tokyo (JP); Hiroaki MATSUBARA, Minato-ku, Tokyo (JP); Kei ITAGAKI, Minato-ku, Tokyo (JP); Masaya TOBA, Minato-ku, Tokyo (JP)

(21) Appl. No.: 18/859,165

(22) PCT Filed: Aug. 31, 2023
(86) PCT No.: PCT/JP2023/032010

§ 371 Date: Oct. 23, 2024

(30) Foreign Application Priority Data
Sep. 2, 2022 (WO) PCT/JP2022/033144

(51) Int. Cl. H01L 21/48; H01L 21/56; H01L 25/065; H01L 25/18; H10B 80/00; H10D 80/30

(52) U.S. Cl. CPC H01L 21/4857; H01L 21/561; H01L 25/0655; H01L 25/18; H10B 80/00; H10D 80/30

(57) ABSTRACT

A method for manufacturing a semiconductor package such as CoWoS-L, the method including: preparing an intermediate structure having a base material with a first main surface and a second main surface on the rear side of the first main surface, and a redistribution layer provided on the first main surface and having an insulating resin layer and wiring, the base material having a resin portion including a through portion that penetrates from the first main surface to the second main surface, and the redistribution layer forming a trench having a bottom surface on which the through portion is exposed; and cutting the through portion along the trench, thereby forming a plurality of wiring structures having base materials divided.

### TECHNICAL FIELD

The present disclosure relates to a method for manufacturing a semiconductor package.

### BACKGROUND ART

An exemplary semiconductor package with a plurality of semiconductor components arranged two-dimensionally is a so-called 2.3-dimensional type, which features an interposer with fine wiring for connecting the multiple semiconductor components (e.g., Patent Literatures 1 and 2).

### CITATION LIST

### Patent Literature

Patent Literature 1: U.S. Patent Application Publication No. 2021/0074646

Patent Literature 2: U.S. Patent Application Publication No. 2021/0074645

### SUMMARY OF INVENTION

### Technical Problem

In a method for manufacturing an electronic component device that has an insulating resin layer and a wiring layer including wiring, multiple wiring structures may be formed from a single intermediate structure on which a wiring layer is formed by cutting a base material, which includes a resin portion, along with the wiring layer. However, since it is typical that the insulating resin layer constituting the wiring layer and the resin portion constituting the base material have different physical properties like hardness, cutting both at the same time using the same method is likely to cause a defect such as damage to one of them. This is particularly challenging when the base material includes a relatively hard resin portion that contains a lot of inorganic filler, as a cutting method suitable for cutting the resin portion is liable to cause delamination or damage to the insulating resin layer that constitutes the wiring layer.

### Solution to Problem

The present disclosure includes the following.

[1]

A method for manufacturing a semiconductor package, comprising:
preparing an intermediate structure comprising a base material and a redistribution layer, the base material having a first main surface and a second main surface on a rear side of the first main surface, the redistribution layer being provided on the first main surface and comprising an insulating resin layer and wiring provided in the insulating resin layer, the base material comprising a resin portion comprising a through portion penetrating from the first main surface to the second main surface, the redistribution layer forming a trench having a bottom surface on which the through portion is exposed;
cutting the through portion along the trench, thereby forming a plurality of wiring structures, each comprising the divided base material and the redistribution layer provided on the base material,
in which the base material comprises
an internal redistribution layer provided inside the first main surface and the second main surface, and comprising an internal insulating resin layer and wiring provided in the internal insulating resin layer,
a plurality of relay wiring portions provided on the side of the internal redistribution layer facing the first main surface and connected to the wiring of the internal redistribution layer;
a first sealing resin layer that seals the relay wiring portion on the internal redistribution layer,
a plurality of semiconductor components provided on the side of the internal redistribution layer facing the second main surface and connected to the wiring of the internal redistribution layer; and
a second sealing resin layer that seals the semiconductor component on the internal redistribution layer,
in which the internal redistribution layer forms an internal trench having a bottom surface on which the first sealing resin layer is exposed,
the second sealing resin layer fills the internal trench,
the bottom surface of the trench and the bottom surface of the internal trench overlap when viewed from a thickness direction of the base material,
the resin portion comprises the first sealing resin layer and the second sealing resin layer,
the through portion is cut along both the trench and the internal trench, and
the plurality of wiring structures being formed each comprises the relay wiring portion and the plurality of semiconductor components electrically connected via the relay wiring portion.
   [2]

The method according to [1], in which
the intermediate structure is prepared in a way that includes
temporarily fixing the plurality of relay wiring portions on a carrier substrate;
forming the first sealing resin layer sealing the relay wiring portion on the carrier substrate;
forming the internal redistribution layer on the side of the relay wiring portion and the first sealing resin layer opposite to the carrier substrate, the redistribution layer forming the internal trench having a bottom surface on which the first sealing resin layer is exposed;
arranging the plurality of semiconductor components on the side of the internal redistribution layer opposite to the relay wiring portion;
forming the second sealing resin layer sealing the semiconductor component and filling the internal trench on the internal redistribution layer;
separating the carrier substrate from the relay wiring portion and the first sealing resin layer to expose the relay wiring portion and the first sealing resin layer, and
forming the redistribution layer on the side of the relay wiring portion and the first sealing resin layer opposite to the internal redistribution layer, the redistribution layer forming the trench having a bottom surface on which the first sealing resin layer is exposed.
   [3]

The method according to [2], in which
the relay wiring portion comprises a semiconductor chip having a main surface comprising an integrated circuit, and
the relay wiring portion is temporarily fixed onto the carrier substrate in an orientation in which the integrated circuit is positioned on the side opposite to the carrier substrate.
   [4]

The method according to [1], in which
the intermediate structure is prepared in a way that includes
temporarily fixing a plurality of the relay wiring portions on a carrier substrate;
forming the first sealing resin layer sealing the relay wiring portion on the carrier substrate;
forming the redistribution layer on the side of the relay wiring portion and the first sealing resin layer opposite to the carrier substrate, the redistribution layer forming the trench having a bottom surface on which the first sealing resin layer is exposed;
separating the carrier substrate from the relay wiring portion and the first sealing resin layer to expose the relay wiring portion and the first sealing resin layer;
forming the internal redistribution layer on the side of the relay wiring portion and the first sealing resin layer opposite to the redistribution layer, the internal redistribution layer having a bottom surface on which the first sealing resin layer is exposed;
arranging a plurality of the semiconductor components on the side of the internal redistribution layer opposite to the carrier substrate; and
forming the second sealing resin layer sealing the semiconductor component and filling the internal trench on the internal redistribution layer.
   [5]

The method according to [4], in which
the relay wiring portion comprises a semiconductor chip having a main surface comprising an integrated circuit, and
the relay wiring portion is temporarily fixed onto the carrier substrate in an orientation in which the integrated circuit is positioned to a side of the carrier substrate.
   [6]

The method according to any one of [1] to [5], in which the resin portion comprises an inorganic filler.

[7]

The method according to any one of [1] to [6], in which
the insulating resin layer and the internal insulating resin layer do not comprise the inorganic filler, or the insulating resin layer and the internal insulating resin layer comprise the inorganic filler, and

In a case where the insulating resin layer and the internal insulating resin layer comprise the inorganic filler, the ratio of the volume of the inorganic filler comprised in the insulating resin layer to the volume of the insulating resin layer and the ratio of the volume of the inorganic filler comprised in the internal insulating resin layer to the volume of the internal insulating resin layer are smaller than the ratio of the volume of the inorganic filler comprised in the resin portion to the volume of the resin layer.

[8]

The method according to any one of [1] to [7], in which
at least one of the redistribution layer or the internal redistribution layer is
formed in a way that includes repeating forming a pattern layer having a pattern including an opening for the wiring and an opening for the trench by exposure and development of a photosensitive resin layer, and forming a conductor layer comprising a via portion that fills the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [9]

The method according to any one of [1] to [7], in which
at least one of the redistribution layer or the internal redistribution layer is
formed in a way that includes repeating removing a part of a resin layer with laser irradiation to form a pattern layer and forming a conductor layer, the pattern layer having a pattern including an opening for the wiring and an opening for the trench, the conductor layer comprising a via portion that fills the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [10]

The method according to any one of [1] to [7], in which
at least one of the redistribution layer or the internal redistribution layer is
formed in a way that includes repeating forming a pattern layer having a pattern including an opening for the wiring through exposure and development of a photosensitive resin layer, and forming a conductor layer comprising a via portion that fills the opening for the wiring,
the insulating resin layer is formed by a plurality of the pattern layers, the wiring is formed by a plurality of the conductor layers, and a part of the formed insulating resin layer is removed with laser irradiation to form the trench.
   [11]

The method according to any one of [1] to [7], in which the width of the trench increases in a direction away from the base material.

[12]

The method according to any one of [1] to [8], in which the width of the internal trench increases in a direction away from the first sealing resin layer.

[13]

The method according to any one of [1] to [12], further comprising mounting the wiring structure on an organic wiring substrate.

[1′]

A method for manufacturing an electronic component device, comprising:
preparing an intermediate structure comprising a base material and a wiring layer, the base material having a first main surface and a second main surface on the rear side of the first main surface, the wiring layer being provided on the first main surface and comprising an insulating resin layer and wiring provided in the insulating resin layer, the base material comprising a resin portion comprising a through portion penetrating from the first main surface to the second main surface, the wiring layer forming a trench having a bottom surface on which the through portion is exposed; and
cutting the through portion along the trench, thereby forming a plurality of wiring structures, each comprising the divided base material and the wiring layer provided on the base material.
   [2′]

The method according to [1′], in which
the resin portion comprises an inorganic filler, and
the insulating resin layer does not comprise an inorganic filler, or the insulating resin layer comprises an inorganic filler, and
in a case where the insulating resin layer comprises an inorganic filler, the ratio of the volume of the inorganic filler comprised in the insulating resin layer to the volume of the insulating resin layer is smaller than the ratio of the volume of the inorganic filler comprised in the resin portion to the volume of the resin layer.
   [3′]

The method according to [1′], in which the intermediate structure is prepared in a way that includes forming the wiring layer, which forms the trench, on the base material.

[4′]

The method according to [1′], in which the intermediate structure is prepared in a way that includes forming the wiring layer, which forms the trench, on a carrier substrate, and shifting the wiring layer from the carrier substrate onto the base material.

[5′]

The method according to any one of [1′] to [4′], in which
the wiring layer is
formed in a way that includes repeating forming a pattern layer through exposure and development of a photosensitive resin layer and forming a conductor layer, the pattern layer having a pattern including an opening for the wiring and an opening for the trench, the conductor layer comprising a via portion filling the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [6′]

The method according to any one of [1′] to [4′], in which
the wiring layer is
formed in a way that includes repeating removing a part of a resin layer with laser irradiation to form a pattern layer and forming a conductor layer having a pattern including an opening for the wiring and an opening for the trench, the conductor layer comprising a via portion filling the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [7′]

The method according to any one of [1′] to [4′], in which
the wiring layer is
formed in a way that includes repeating forming a pattern layer through exposure and development of a photosensitive resin layer and forming a conductor layer, the pattern layer having a pattern including an opening for the wiring, the conductor layer comprising a via portion filling the opening for the wiring, and
the insulating resin layer is formed by a plurality of the pattern layers, the wiring is formed by a plurality of the conductor layers, and a part of the formed insulating resin layer is removed with laser irradiation to form the trench.
   [8′]

The method according to any one of [1′] to [7′], further comprising mounting a plurality of semiconductor components on the wiring layer, and
in which each of the formed plurality of wiring structures comprises one or more of the semiconductor components.
   [9′]

The method according to any one of [1′] to [7′], in which
the base material further comprises an internal wiring layer exposed on the second main surface,
the internal wiring layer forms an internal trench filled with the through portion of the resin portion,
the method further comprises mounting a plurality of semiconductor components on the internal wiring layer,
the through portion is cut along the trench and the internal trench, and
each of the formed plurality of wiring structures comprises one or more of the semiconductor components.
   [10′]

The method according to [8] or [9], in which
the base material further comprises a relay wiring portion comprising relay wiring electrically connected to a plurality of the semiconductor components, and the relay wiring portion is sealed by the resin portion, and
the formed plurality of wiring structures each comprises the relay wiring portion and two or more of the semiconductor components electrically connected via the relay wiring portion.
   [11′]

The method according to any one of [1′] to [10′], in which the width of the trench increases in the direction away from the base material.

[12′]

The method according to any one of [1] to [11′], further comprising mounting the wiring structure on an organic wiring substrate.

### Advantageous Effects of Invention

A method is disclosed for easily manufacturing a wiring structure including a base material that has a resin portion containing a lot of inorganic fillers and a wiring layer provided on the base material. This method is applicable, for example, to the fabrication of 2.3-dimensional semiconductor packages. The method disclosed herein is applicable, for example, to the fabrication of semiconductor packages having a structure similar to that of semiconductor packages known to those skilled in the art as CoWoS-L, S-Connect, FO-EB, FO-CoS, or InFO-L.

### BRIEF DESCRIPTION OF DRAWINGS

FIG. 1 is a process diagram illustrating an example of a method for manufacturing an electronic component device.

FIG. 2 is a process diagram illustrating an example of a method for manufacturing an electronic component device.

FIG. 3 is a process diagram illustrating an example of a method for manufacturing an electronic component device.

FIG. 4 is a process diagram illustrating an example of a method for manufacturing an electronic component device.

FIG. 5 is a process diagram illustrating an example of a method for manufacturing an electronic component device having a semiconductor component.

FIG. 6 is a process diagram illustrating an example of a method for manufacturing an electronic component device having a semiconductor component.

FIG. 7 is a process diagram illustrating an example of a method for manufacturing an electronic component device having a semiconductor component.

FIG. 8 is a process diagram illustrating an example of a method for manufacturing an electronic component device having a semiconductor component.

FIG. 9 is a process diagram illustrating an example of a method for manufacturing an electronic component device having a semiconductor component.

FIG. 10 is a process diagram illustrating an example of a method for manufacturing an electronic component device having a semiconductor component.

FIG. 11 is a process diagram illustrating an example of a method for manufacturing an electronic component device having a semiconductor component.

FIG. 12 is a process diagram illustrating an example of a method for manufacturing an electronic component device having a semiconductor component.

FIG. 13 is a process diagram illustrating an example of a method for manufacturing an electronic component device having a semiconductor component.

FIG. 14 is a process diagram illustrating an example of a method for manufacturing an electronic component device having a semiconductor component.

FIG. 15 is a process diagram illustrating an example of a method for manufacturing an electronic component device having a semiconductor component.

FIG. 16 is a process diagram illustrating an example of a method for manufacturing an electronic component device having a semiconductor component.

FIG. 17 is a process diagram illustrating an example of a method for manufacturing an electronic component device having a semiconductor component.

FIG. 18 is a process diagram illustrating an example of a method for manufacturing an electronic component device having a semiconductor component.

FIG. 19 is a process diagram illustrating an example of a method for manufacturing an electronic component device having a semiconductor component.

FIG. 20 is a process diagram illustrating an example of a method for manufacturing an electronic component device having a semiconductor component.

FIG. 21 is a process diagram illustrating an example of a method for manufacturing an electronic component device having a semiconductor component.

FIG. 22 is a process diagram illustrating an example of a method for manufacturing an electronic component device having a semiconductor component.

FIG. 23 is a process diagram illustrating an example of a method for manufacturing an electronic component device having a semiconductor component.

FIG. 24 is a process diagram illustrating an example of a method for manufacturing an electronic component device having semiconductor components.

FIG. 25 is a process diagram illustrating an example of a method for manufacturing an electronic component device having a semiconductor component.

### DESCRIPTION OF EMBODIMENTS

The present disclosure is not limited to the following examples. In the following examples, duplicated descriptions may be omitted.

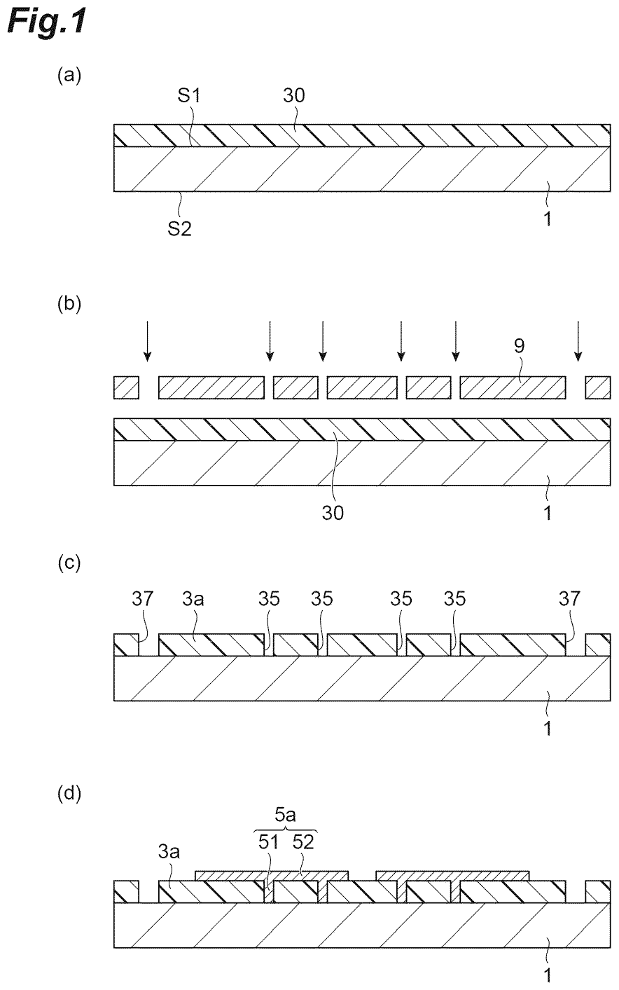

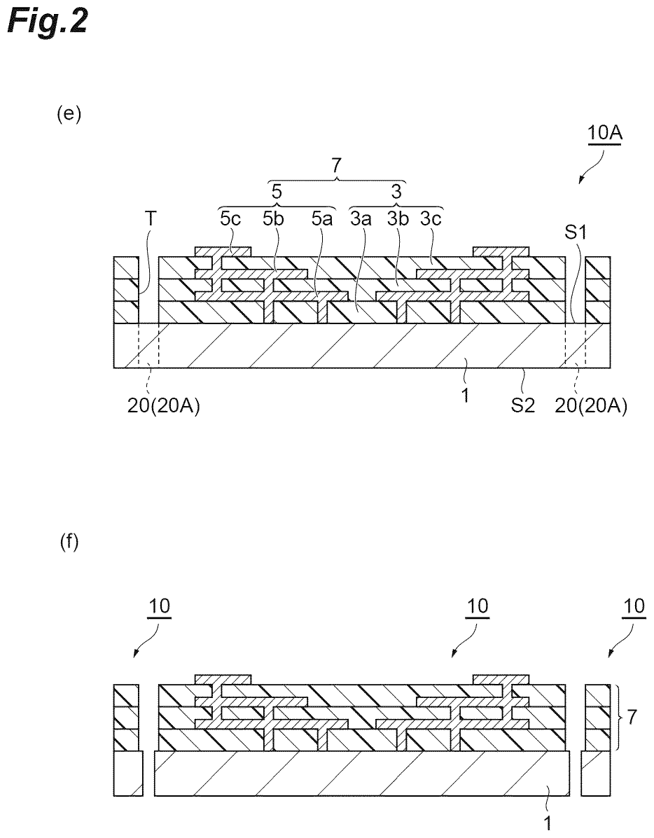

FIGS. 1 and 2 are process diagrams illustrating an example of a method for manufacturing an electronic component device. The method illustrated in FIG. 1 and FIG. 2 includes preparing an intermediate structure 10A having a base material 1 and a wiring layer 7. The base material 1 has a first main surface S1 and a second main surface S2 on the rear side of the first main surface S1. The wiring layer 7 is provided on the first main surface S1 and has an insulating resin layer 3 and wiring 5 provided in the insulating resin layer 3. The base material 1 has a resin portion 20 including a through portion 20A penetrating from the first main surface S1 to the second main surface S2. The insulating resin layer 3 forms a trench T having a bottom surface that exposes the through portion 20A. The method also includes cutting the through portion 20A along the trench T to form a plurality of wiring structures 10, each having the base material 1 divided and the wiring layer 7 provided on the base material 1.

The through portion 20A is a portion of the resin portion 20 that penetrates from the first main surface S1 to the second main surface S2. The resin portion 20 includes at least the through portion 20A and can be a member integrally formed from a resin material such as a sealing material. The entire first main surface S1 of the base material 1 may also be the surface of the resin portion 20. Alternatively, in addition to the resin portion 20 including the through portion 20A, a relay wiring portion, a semiconductor component, or both of these described below may be provided in the base material 1, with the relay wiring portion or the semiconductor component exposed to the first main surface S1.

The resin portion 20 may contain a resin and an inorganic filler. The insulating resin layer 3 may contain a resin and an inorganic filler. In the case where the insulating resin layer 3 contains an inorganic filler, the ratio of the volume of the inorganic filler contained in the insulating resin layer 3 to the volume of the insulating resin layer 3 is smaller than the ratio of the volume of the inorganic filler contained in the resin portion 20 to the volume of the resin portion 20. Due to the difference in the ratio of inorganic fillers, the resin portion 20 is relatively harder. Different hardnesses often result in different suitable cutting conditions, but according to the method disclosed herein, since only the resin portion 20 (the through portion 20A) is cut, it is possible to employ cutting conditions suitable for cutting the resin portion 20 while avoiding any influence on the insulating resin layer 3. The resin portion 20 (the through portion 20A) is cut, for example, by a rotating blade.

The ratio of the volume of the inorganic filler in the resin portion 20 to the volume of the resin portion 20 may be, for example, 10% or more and 95% or less by volume. The ratio of the volume of the inorganic filler in the insulating resin layer 3 to the volume of the insulating resin layer 3 may be, for example, 0% or more and 50% or less by volume.

In the example of FIGS. 1 and 2, the wiring layer 7 is formed by repeatedly forming a pattern layer 3a having a pattern including an opening for the wiring 35 used for the wiring and an opening for the trench 37 used for the trench by exposing and developing a photosensitive resin layer 30 formed on the first main surface S1 of the base material 1, and forming a conductor layer 5a including a via portion 51 filling the opening for the wiring 35 and a wiring pattern portion 52 provided on the pattern layer 3a. The insulating resin layer 3 is formed by the first pattern layer 3a, a second pattern layer 3b, and a third pattern layer 3c, which are formed in sequence from the side of the base material 1. The wiring 5 is formed by the first conductor layer 5a, a second conductor layer 5b, and a third conductor layer 5c, which are formed in sequence from the side of the base material 1. The trench T penetrating the insulating resin layer 3 is formed by connecting the multiple openings for the trench 37 formed by the plurality of pattern layers 3a, 3b, and 3c.

The photosensitive resin layer 30 and the pattern layers 3a, 3b, and 3c can be formed using conventional resist materials that are used to form an insulating resin layer of a wiring laver. For the exposure of the resin layer 30, active light rays such as ultraviolet light are applied through a mask 9, which has an opening provided at a position corresponding to the opening for the wiring 35 and the opening for the trench 37. Instead of using the exposure and development method, a part of the resin layer 30 may be removed by laser irradiation to form the pattern layers 3a, 3b, and 3c, which have a pattern including the opening for the wiring 35 and the opening for the trench 37. In this case, the resin layer 30 may be non-photosensitive.

The conductor layers 5a, 5b, and 5c and the wiring 5 can be formed using conventional methods such as plating, printing of conductor paste, or sputtering.

The wiring layer 7 is used, for example, as a redistribution layer connected to a semiconductor component including an IC chip. The number of pattern layers and conductor layers that constitute the wiring layer 7 is not limited to a particular number, but may be, for example, 2 or more and 8 or less, respectively. The thickness of the entire wiring layer 7 may be, for example, 10 μm or more and 150 μm or less.

The intermediate structure 10A may be prepared by a method that includes forming the wiring layer 7, which forms the trench T, on a carrier substrate separate from the base material 1, and shifting the wiring layer 7 from the carrier substrate onto the base material 1.

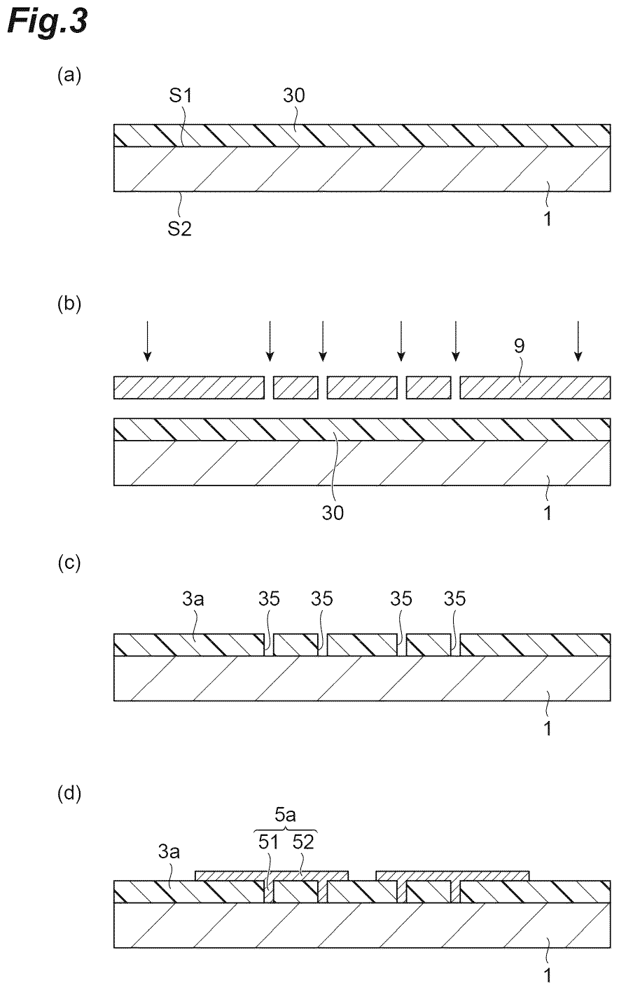

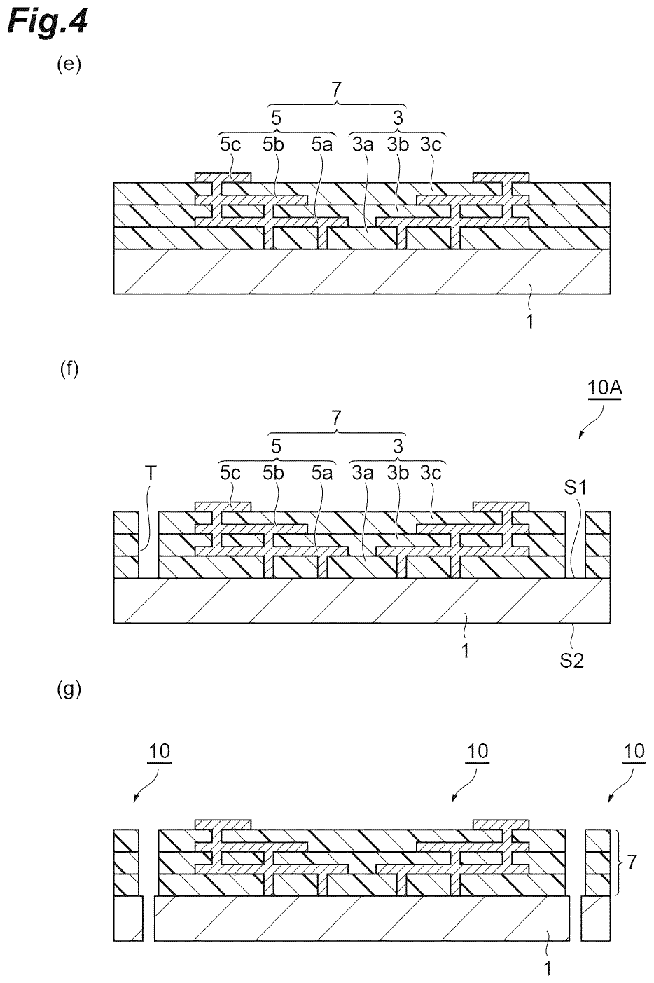

FIGS. 3 and 4 are process diagrams illustrating another exemplary method for manufacturing an electronic component device. In the case of the method illustrated in FIGS. 3 and 4, the wiring layer 7 is formed in a way, which includes repeatedly forming a pattern layer 3a having a pattern including an opening for the wiring 35 used for the wiring by exposure and development of the photosensitive resin layer 30 and forming a conductor layer 5a including a via portion 51 that fills the opening for the wiring 35 and a wiring pattern portion 52 provided on the pattern layer 3a. As in the method for FIGS. 1 and 2, the insulating resin layer 3 is formed by the plurality of pattern layers 3a, 3b, and 3c, and the wiring 5 is formed by the plurality of conductor layers 5a, 5b, and 5c. Then, as illustrated in FIG. 4(f), a part of the formed insulating resin layer 3 is removed using laser irradiation to form the trench T.

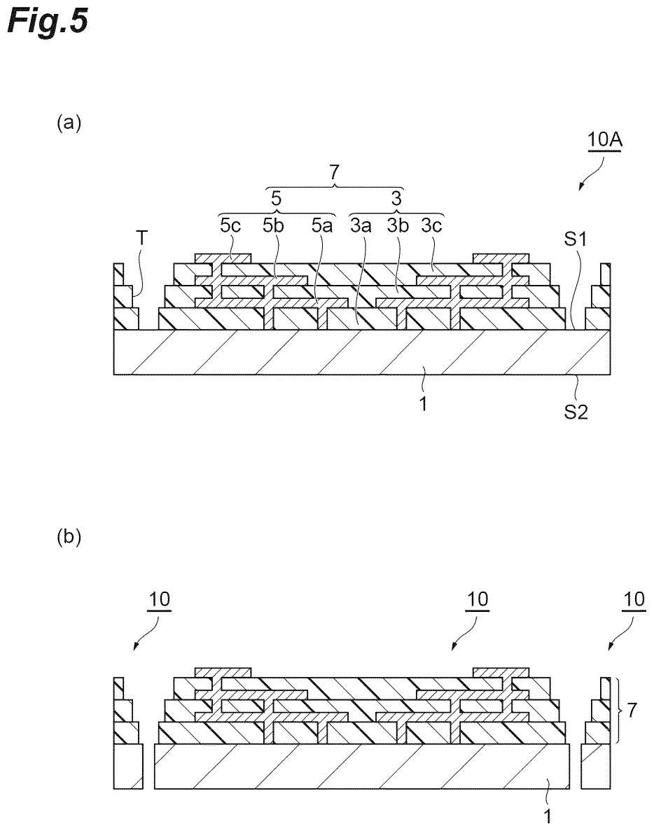

As illustrated in another example in FIG. 5, the trench T may be formed with a width that widens in the direction away from the base material 1. By varying the width of the opening for the trench formed by the multiple pattern layers 3a, 3b, and 3c, it is possible to form the trench T with a gradually widening width. In the case where the end face of the trench T (insulating resin layer 3) is inclined in this way, the occurrence of cracks or delamination starting from the edge of the insulating resin layer 3 can be suppressed.

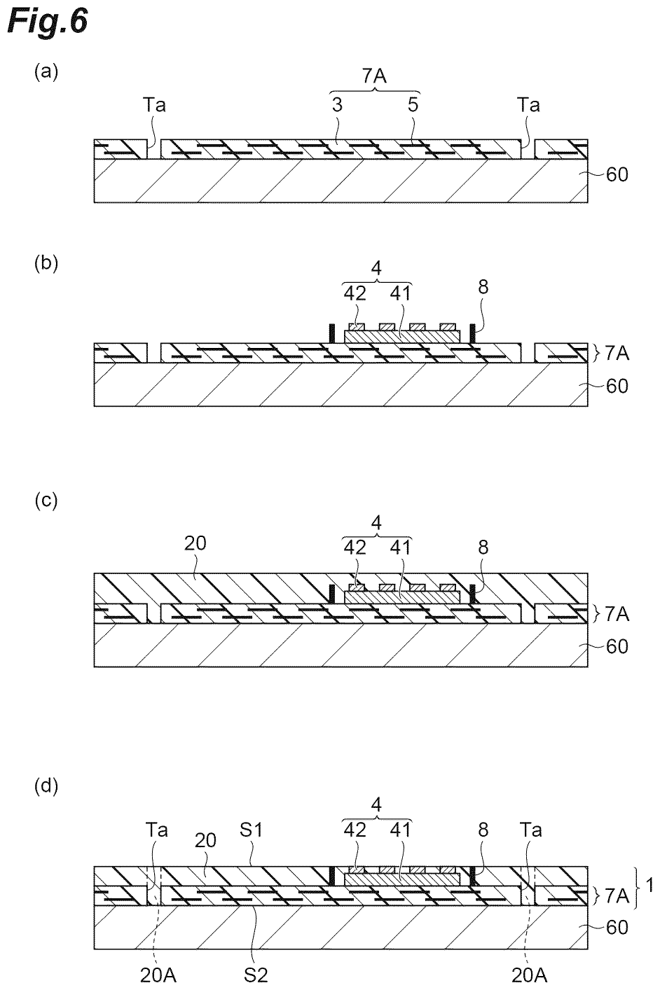

FIGS. 6, 7, 8, and 9 are process diagrams illustrating an example of a method for manufacturing an electronic component device having multiple semiconductor components. In the method illustrated in FIGS. 6 to 9, as illustrated in FIG. 6, the base material 1 is formed in a way that includes forming an internal wiring layer 7A forming an internal trench Ta, arranging a relay wiring portion 4 and a copper pillar 8 on the internal wiring layer 7A, forming the resin portion 20 that seals the relay wiring portion 4, and removing the surface layer portion of the resin portion 20 opposite to the internal wiring layer 7A to form a flat surface that exposes the relay wiring portion 4 and the copper pillar 8. The base material 1 being formed includes the internal wiring layer 7A, the relay wiring portion 4, and the resin portion 20. The resin portion 20 includes a portion that fills the internal trench Ta of the internal wiring layer 7A and includes a through portion 20A that penetrates from the first main surface SI to the second main surface S2 on the rear side. The internal wiring layer 7A is exposed on the second main surface S2 of the base material 1. The internal wiring layer 7A can be formed by exposure and development of a photosensitive resin layer, laser irradiation, or a combination of these, similar to the method illustrated in FIGS. 1 to 4.

The relay wiring portion 4 has a main body 41 including relay wiring electrically connected to a plurality of semiconductor components and has a terminal 42 provided on the outer surface of the main body 41. The relay wiring portion 4 is arranged on the internal wiring layer 7A in the orientation in which the terminal 42 is positioned on the side opposite to the internal wiring layer 7A. The relay wiring portion 4 may be a silicon interposer including a silicon substrate. The copper pillar 8 can be formed using conventional by conventional methods such as plating or printing of a conductive paste. The copper pillar 8 is electrically connected to the wiring 5 in the internal wiring layer 7A.

The resin portion 20 can be formed using conventional sealing materials such as a thermosetting resin composition containing an inorganic filler. The inorganic filler may include, for example, silica particles.

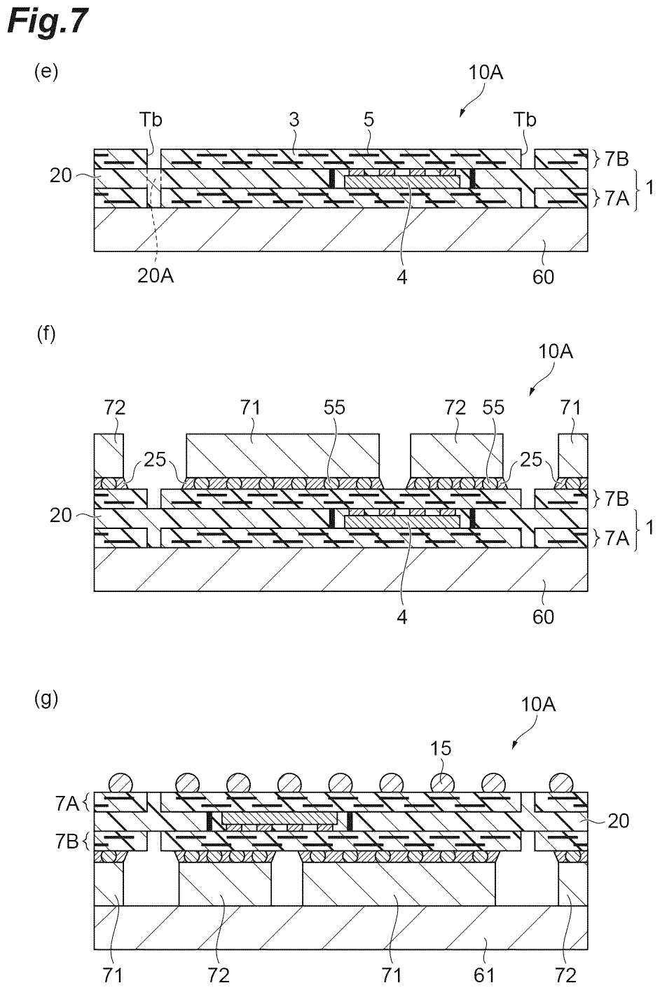

Subsequently, as illustrated in FIG. 7(e), a wiring layer 7B is formed on the first main surface S1 of the base material 1, forming a trench Tb having a bottom surface that exposes the through portion 20A. The trench Tb is formed at a position overlapping with the internal trench Ta when viewed from the thickness direction of the base material 1. The wiring layer 7B can be formed using a method similar to that illustrated in FIGS. 1 to 4. The wiring 5 in the wiring layer 7B is electrically connected to the relay wiring portion 4 and the copper pillar 8.

On the formed wiring layer 7B, a plurality of semiconductor components 71 and 72 are mounted (FIG. 7(f)). The semiconductor components 71 and 72 each have a bump 55, and the semiconductor components 71 and 72 are electrically connected to the wiring layer 7B via the bump 55. The space between the semiconductor components 71 and 72 and the wiring layer 7B is filled with an underfill material 25.

The intermediate structure 10A having the base material 1, the wiring layer 7B, and the semiconductor components 71 and 72 is shifted onto a carrier substrate 61, which is separate from the carrier substrate 60, in the orientation in which the semiconductor components 71 and 72 are positioned on the side of the carrier substrate 61, and in this state, a bump 15 is provided on the internal wiring layer 7A (FIG. 7(g)).

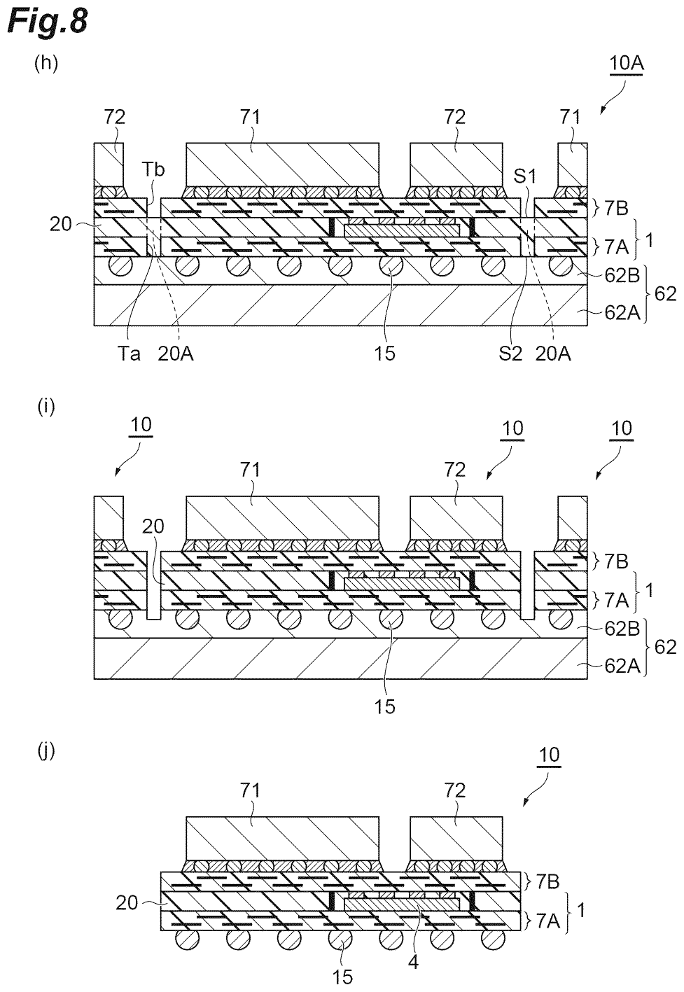

Then, as illustrated in FIG. 8(a), the intermediate structure 10A is shifted onto another carrier substrate 62. The carrier substrate 62 has a support substrate 62A and a temporary fixing material layer 62B provided on the support substrate 62A. The intermediate structure 10A is temporarily fixed to the carrier substrate 62 in the orientation in which the bump 15 contacts the temporary fixing material layer 62B. In this state, the through portion 20A of the resin portion 20 is cut from the side of the trench Tb along the trench Tb and the internal trench Ta, and thus a plurality of wiring structures 10 is formed on the carrier substrate 62 (FIG. 8(i)).

The wiring structure 10 is delaminated from the carrier substrate 62 (FIG. 8(j)). The wiring structure 10 is an electronic component device having the relay wiring portion 4 and the plurality of semiconductor components 71 and 72, that is, a semiconductor package. The plurality of semiconductor components 71 and 72 are electrically connected through the relay wiring portion 4. The semiconductor components 71 and 72 constituting one wiring structure 10 can be components having different functions. For example, the semiconductor component 71 may be a system-on-chip (SoC), and the semiconductor component 72 may be a memory. A single wiring structure 10 (semiconductor package) may also have a plurality of semiconductor components of the same type.

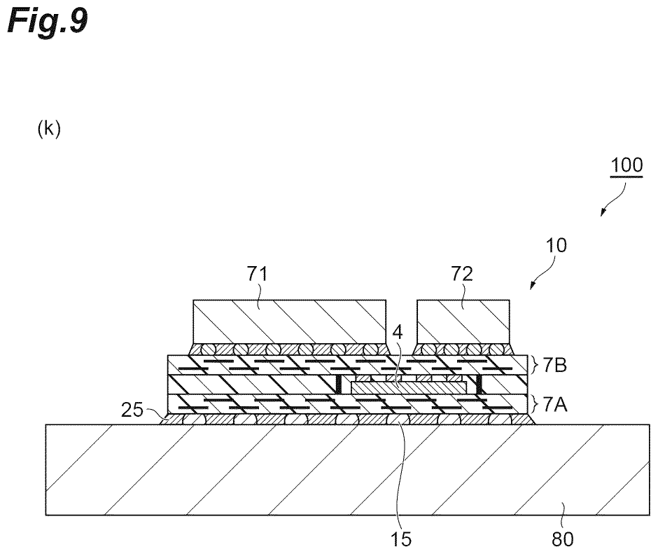

As illustrated in FIG. 9, the wiring structure 10 is mounted on an organic wiring substrate 80 to obtain an electronic component device 100. The wiring structure 10 is electrically connected to the organic wiring substrate 80 via the bump 15. The underfill material 25 may be filled between the wiring structure 10 and the organic wiring substrate 80. Various electronic components other than the wiring structure 10 may be mounted on one organic wiring substrate 80.

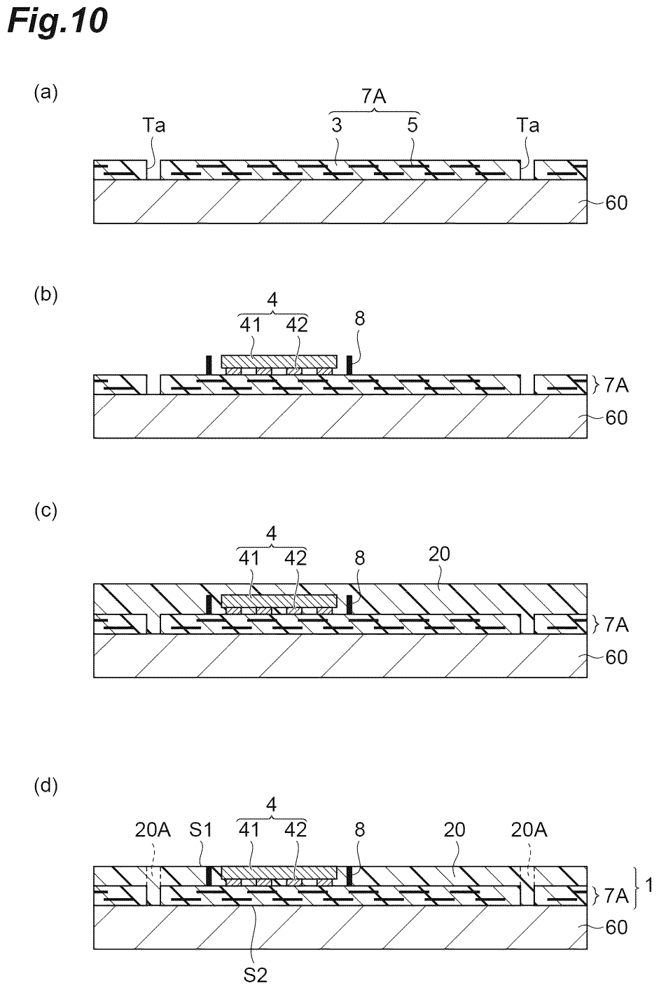

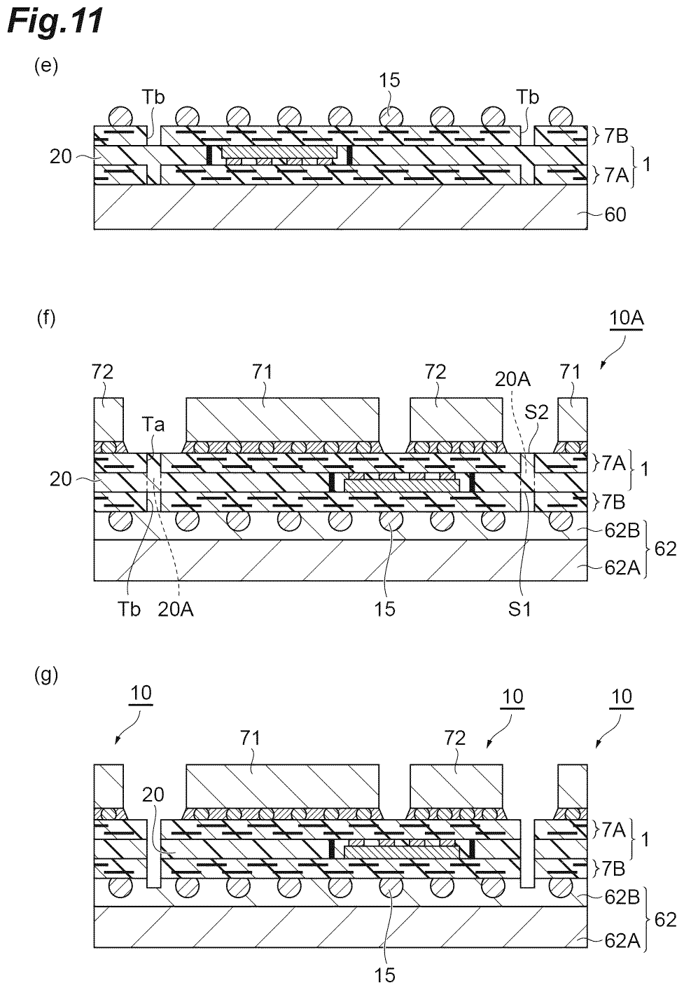

FIGS. 10 and 11 are process diagrams illustrating another example of a method for manufacturing an electronic component device having multiple semiconductor components. The method illustrated in FIGS. 10 and 11 differs from the methods illustrated in FIGS. 7 to 9 in that the relay wiring portion 4 is arranged on the internal wiring layer 7A in the orientation in which the terminal 42 is positioned on the side of the internal wiring layer 7A (FIG. 10(b)), and in that multiple semiconductor components 71 and 72 are mounted on the internal wiring layer 7A (FIG. 11(f)). The bump 15 is provided on the wiring layer 7B with the intermediate structure 10A temporarily fixed to the carrier substrate 60 (FIG. 11(e)).

As illustrated in FIGS. 11(f) and 11(g), while the intermediate structure 10A is temporarily fixed to the carrier substrate 62, the through portion 20A of the resin portion 20 is cut from the side of the internal trench Ta along the trench Tb and the internal trench Ta to form the plurality of wiring structures 10 on the carrier substrate 62. The formed wiring structures 10 can be delaminated from the carrier substrate 62 and mounted on an organic wiring substrate.

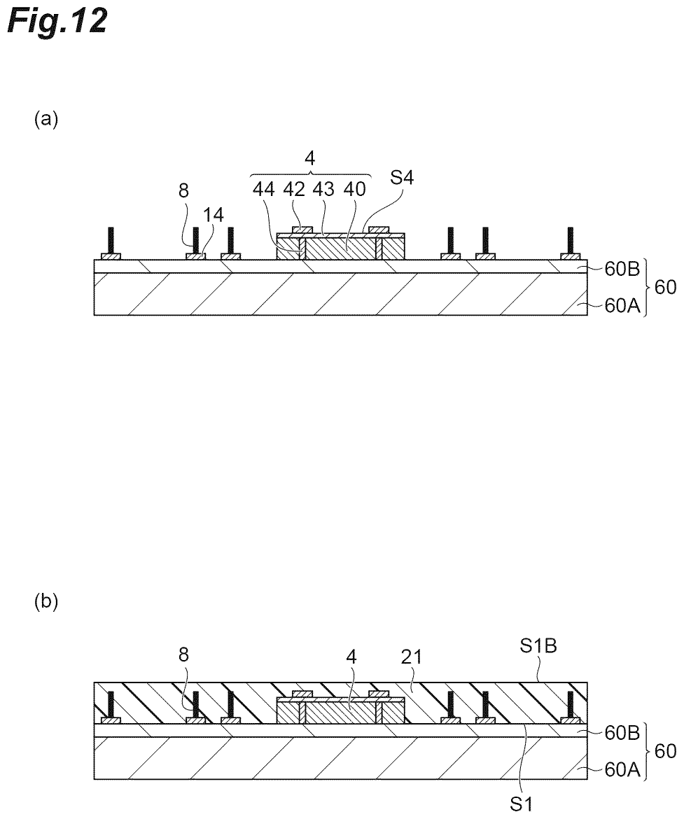

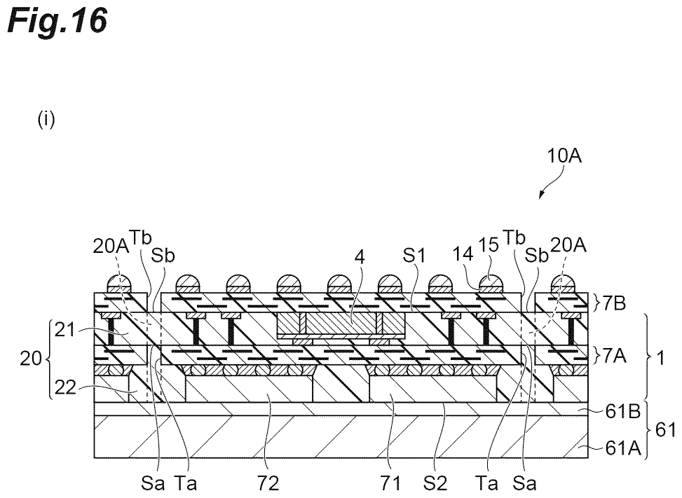

FIGS. 12, 13, 14, 15, 16, 17, and 18 are also process diagrams illustrating, in partial cross-section, an example of a method for manufacturing an electronic component device (semiconductor package) having a plurality of semiconductor components. In this example, as illustrated in FIG. 16, the base material 1 has an internal redistribution layer 7A provided on the inside of the first main surface S1 and the second main surface S2, a plurality of relay wiring portions 4 provided on the side of the first main surface S1 of the internal redistribution layer 7A, a first sealing resin layer 21 that seals the relay wiring portions 4 between the internal redistribution layer 7A and a redistribution layer 7B, a plurality of semiconductor components 71 and 72 provided on the side of the second main surface S2 of the internal redistribution layer 7A, and a second sealing resin layer 22 that seals the semiconductor components 71 and 72 on the internal redistribution layer 7A. The redistribution layer 7B provided on the first main surface S1 of the base material 1 forms a trench Tb having a bottom surface Sb that exposes the first sealing resin layer 21.

The internal redistribution layer 7A has an internal insulating resin layer and wiring provided in the internal insulating resin layer. The internal insulating resin layer and the wiring of the internal redistribution layer 7A can have a similar configuration to the insulating resin layer and the wiring of the above-mentioned wiring layer or internal wiring layer. The relay wiring portion 4 is connected to the wiring of the internal redistribution layer 7A. The semiconductor components 71 and 72 are also connected to the wiring of the internal redistribution layer 7A. The relay wiring portion 4 may be connected to the wiring of the redistribution layer 7B.

The internal redistribution layer 7A forms an internal trench Ta having a bottom surface Sa that exposes the first sealing resin layer 21. The second sealing resin layer 22 fills the internal trench Ta. However, the second sealing resin layer 22 does not necessarily need to completely fill the internal trench Ta. The bottom surface Sb of the trench Tb and the bottom surface Sa of the internal trench Ta overlap when viewed from the thickness direction of the base material 1.

In the example of FIGS. 12 to 18, the intermediate structure 10A having the base material 1 and the redistribution layer 7B is prepared, and then the through portion 20A is cut along the trench Tb and the internal trench Ta to form the base material 1 and the plurality of wiring structures 10 having the redistribution layer 7B. Each of the formed plurality of wiring structures 10 has the relay wiring portion 4 and the two or more semiconductor components 71 and 72 electrically connected via the relay wiring portion 4. The two or more semiconductor components 71 and 72 may be the same or different. For example, the semiconductor component 71 may be a system-on-chip (SoC), and the semiconductor component 72 may be a memory.

To provide the intermediate structure 10A, as illustrated in FIG. 12(a), the carrier substrate 60 having a support substrate 60A and a temporary fixing material layer 60B provided on the support substrate 60A is prepared, and the relay wiring portion 4 is temporarily fixed on the temporary fixing material layer 60B of the carrier substrate 60. The relay wiring portion 4 is an interposer that includes a semiconductor chip 40 with a main surface S4 including an integrated circuit 43 and a terminal 42 provided on the main surface S4. The semiconductor chip 40 may also have a conductive via 44 connected to the terminal 42. The relay wiring portion 4 is temporarily fixed on the carrier substrate 60 in the orientation in which the main surface S4 including the integrated circuit 43 is positioned on the side opposite to the carrier substrate 60. A plurality of relay wiring portions 4 are temporarily fixed on one carrier substrate 60. A plurality of electrodes 14 may be arranged on the carrier substrate 60 in the periphery of the relay wiring portion 4, and a copper pillar 8 may be fixed on each of the electrodes 14.

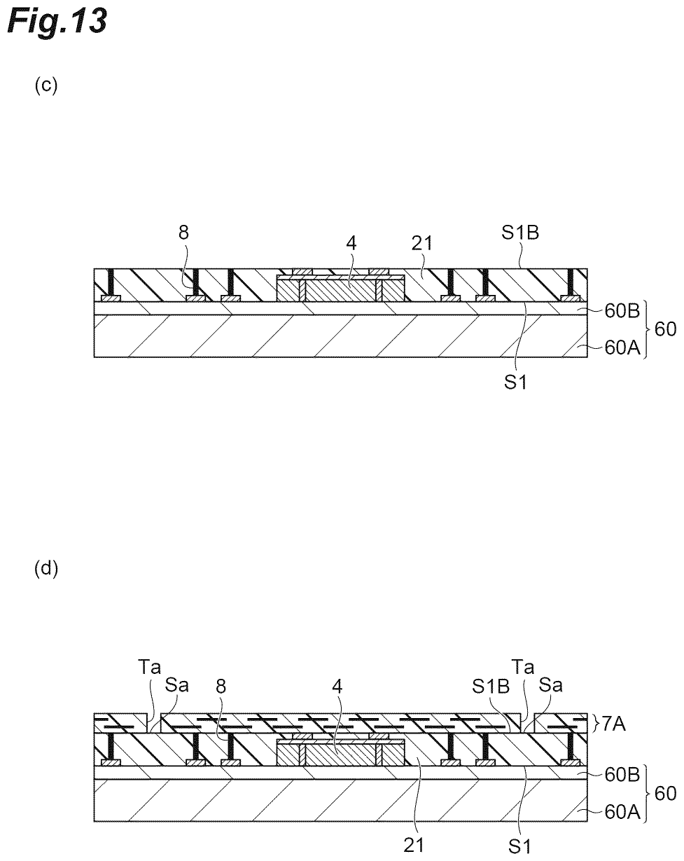

Subsequently, the first sealing resin layer 21 that seals the relay wiring portion 4 is formed on the carrier substrate 60 (FIG. 12(b)). The first sealing resin layer 21 is a plate-shaped resin molded body having the first main surface S1 in contact with the carrier substrate 60. The relay wiring portion 4 is sealed on the inside of the rear surface S1B opposite to the first main surface S1. A part of the first sealing resin layer 21 is removed from the side of the rear surface S1B to form the rear surface S1B which is the surface that exposes the relay wiring portion 4 and the copper pillar 8 (FIG. 13(c)). The first sealing resin layer 21 can be a layer containing resin and inorganic filler formed from resin materials such as conventional sealing materials, as in the example of the resin portion 20 described above. The first sealing resin layer 21 can be removed using conventional methods such as chemical-mechanical polishing.

As illustrated in FIG. 13(d), the internal redistribution layer 7A forming the internal trench Ta having the bottom surface Sa that exposes the first sealing resin layer 21 is formed on the relay wiring portion 4 and the first sealing resin layer on the side opposite to the carrier substrate 60. The internal redistribution layer 7A can be formed using a method similar to the one described for wiring layer. The first sealing resin layer 21 includes a through portion penetrating from the bottom surface Sa (rear surface S1B) of the internal trench Ta to the first main surface S1.

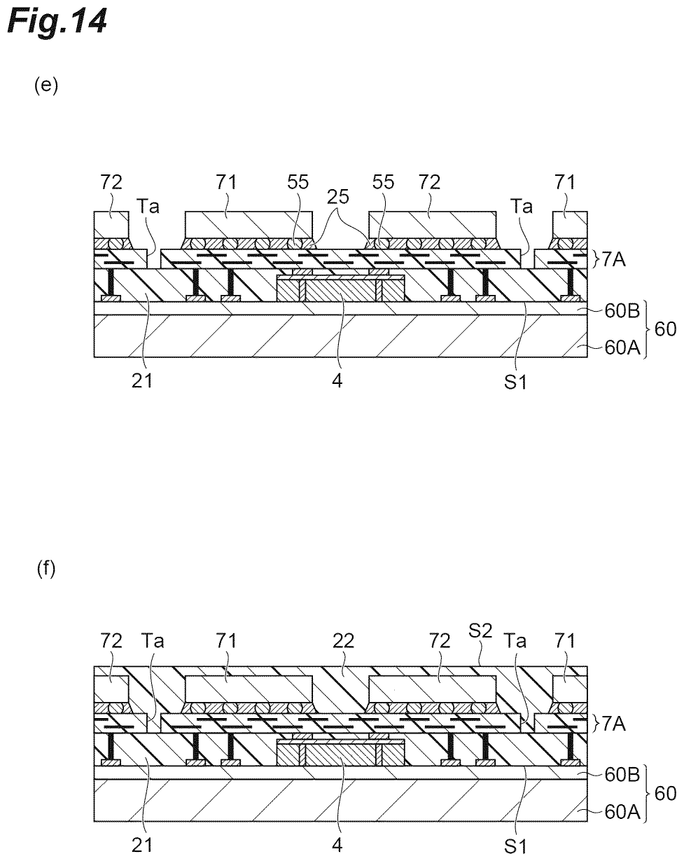

As illustrated in FIG. 14(e), the plurality of semiconductor components 71 and 72 are arranged on the side of the internal redistribution layer 7A opposite to the relay wiring portion 4 and the first sealing resin layer 21. Each of the semiconductor components 71 and 72 has the bump 55, and the semiconductor components 71 and 72 may be electrically connected to the wiring of the internal redistribution layer 7A via the bump 55. In this case, the gap between the semiconductor components 71 and 72 and the internal redistribution layer 7A may be filled with the underfill material 25.

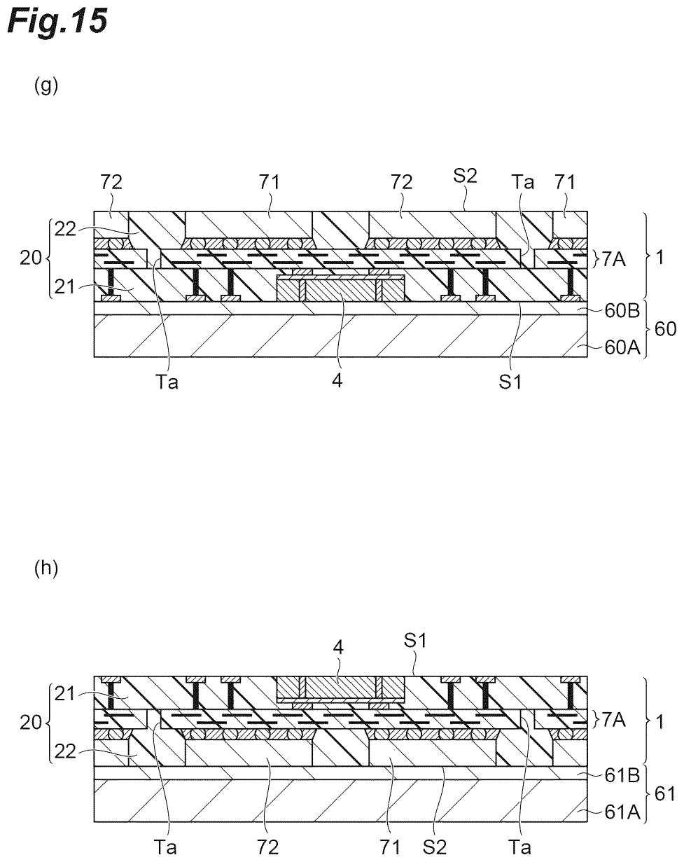

Then, the second sealing resin layer 22 that seals the semiconductor components 71 and 72, is formed on the internal redistribution layer 7A to (FIG. 14(f)). The second sealing resin layer 22 is a plate-shaped resin molded body having a second main surface S2. The second sealing resin layer 22 can be a layer containing resin and inorganic filler, which is formed of a resin material such as conventional sealing materials, as in the example of the resin portion 20 described above. The semiconductor components 71 and 72 are sealed on the inside of the second main surface S2. A part of the second sealing resin layer 22 may be removed from the side of the second main surface S2 to form the second main surface S2 that exposes the semiconductor components 71 and 72 (FIG. 15(g)). The second sealing resin layer 22 may also be removed by conventional methods such as chemical-mechanical polishing. At this stage, the base material 1 having the first main surface S1 and the second main surface S2 is formed on the carrier substrate 60. The first sealing resin layer 21 and the second sealing resin layer 22 form the resin portion 20. As illustrated in FIG. 15(h), the carrier substrate 60 is separated from the formed base material 1, and then the base material 1 is temporarily fixed on another carrier substrate 61 in the orientation in which the second main surface S2 (semiconductor components 71 and 72 and the second sealing resin layer 22) is positioned on the side of the carrier substrate 61. The carrier substrate 61 has a support substrate 61 A and a temporary fixing material layer 61B provided on the support substrate 61A.

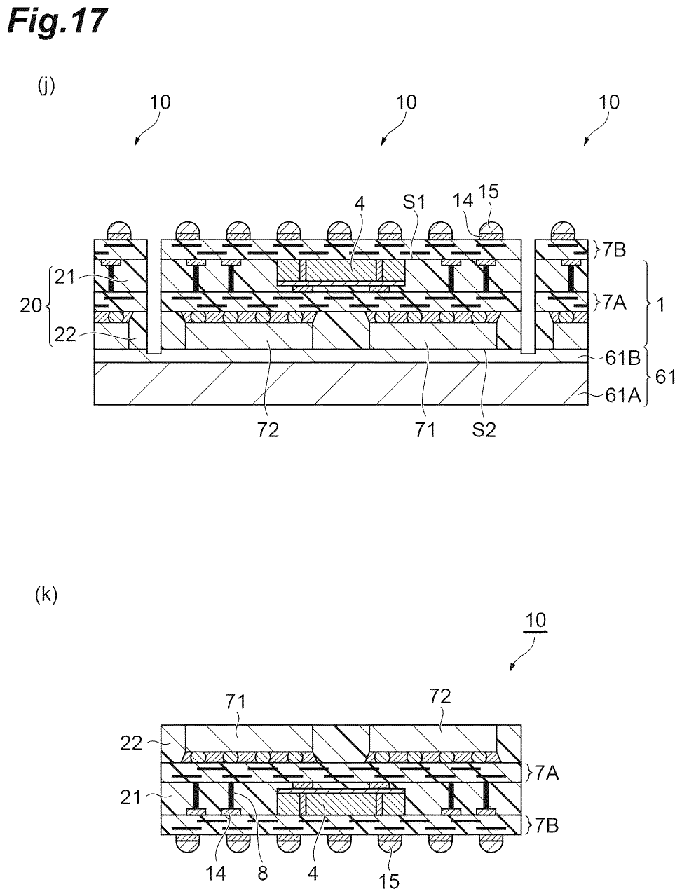

As illustrated in FIG. 16, the redistribution layer 7B is formed on the first main surface S1 of the base material 1, forming the trench Tb having the bottom surface Sb that exposes the first sealing resin layer 21. The redistribution layer 7B can be formed using a method similar to the one described for the wiring layer. The portion of the first sealing resin layer 21 and the second sealing resin layer 22 where the bottom surface Sb of the trench Tb and the bottom surface Sa of the internal trench Ta overlap when viewed from the thickness direction of the base material 1 is the through portion 20A. In this state, the base material 1 (resin portion 20) is cut at the position of the through portions 20A along the trench Tb and the internal trench Ta, as illustrated in FIG. 17(j), to form the plurality of wiring structures 10 on the carrier substrate 62. Before or after the base material 1 is cut, the bump 15 may be formed on the electrodes 14 of the redistribution layer 7B. The formed wiring structures 10 is separated from the carrier substrate 61 as illustrated in FIG. 17(k). The obtained wiring structure 10 may be used as a semiconductor package.

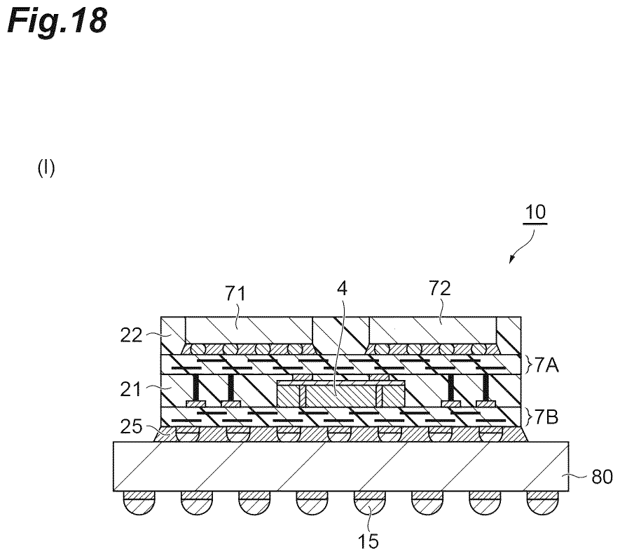

As illustrated in FIG. 18, the wiring structure 10 may be mounted on the organic wiring substrate 80 (semiconductor package substrate) to obtain a semiconductor package having the wiring structure 10 and the semiconductor package substrate (organic wiring substrate 80). The space between the wiring structure 10 and the organic wiring substrate 80 may be filled with the underfill material 25. The bump 15 may also be provided on the surface of the organic wiring substrate 80 opposite to the wiring structure 10.

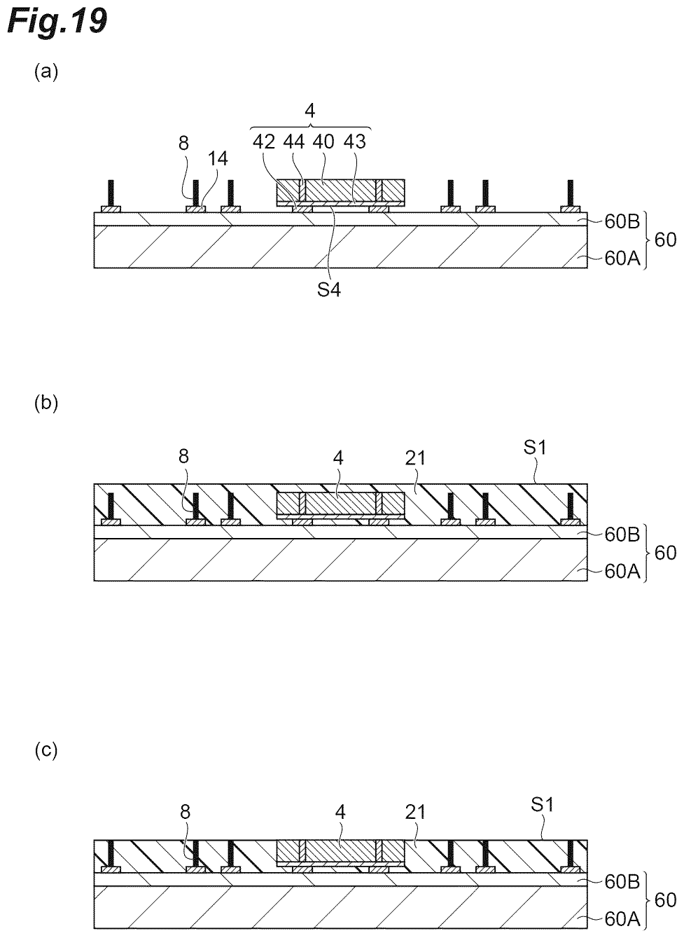

FIGS. 19, 20, 21, 22, 23, 24, and 25 are also process diagrams illustrating, in partial cross-section, an example of a method for manufacturing an electronic component device (semiconductor package) having multiple semiconductor components. The example of FIGS. 19 to 25 differs from the example of FIGS. 12 to 18 in that the relay wiring portion 4 is temporarily fixed on the carrier substrate 60 in the orientation in which the main surface S4 including the integrated circuit 43 is positioned on the side of the carrier substrate 60 as illustrated in FIG. 19. The structure of the wiring structure 10 formed is essentially the same as the structure of the wiring structure 10 obtained by the method of the example of FIGS. 12 to 18, except that the electrode 14 connected to the copper pillar 8 is provided on the internal wiring layer 7A.

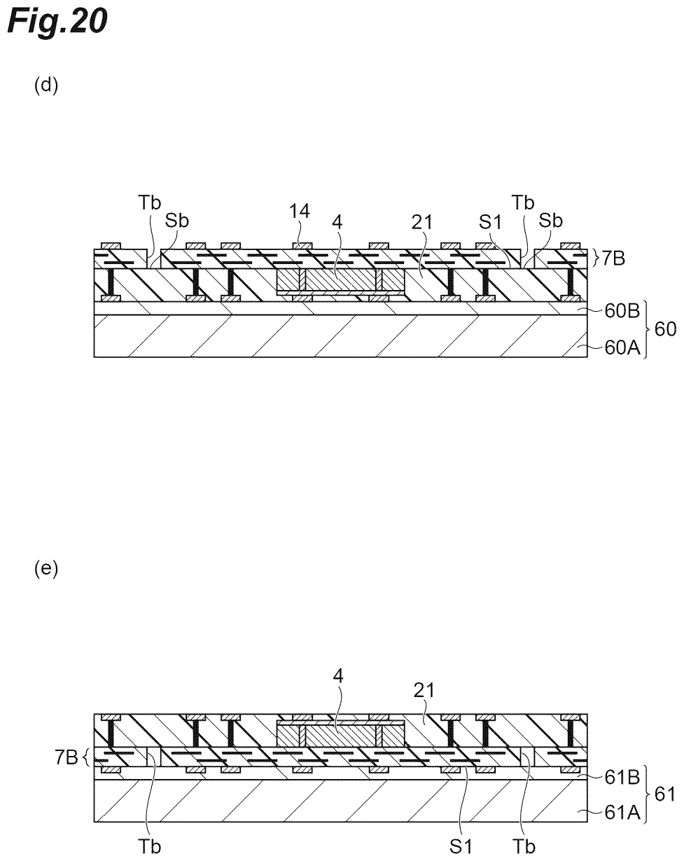

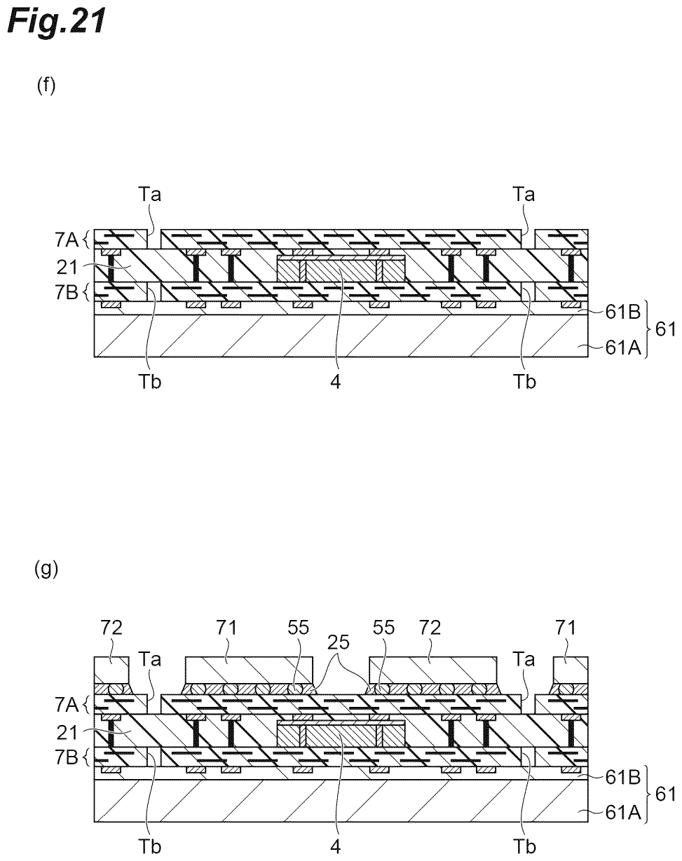

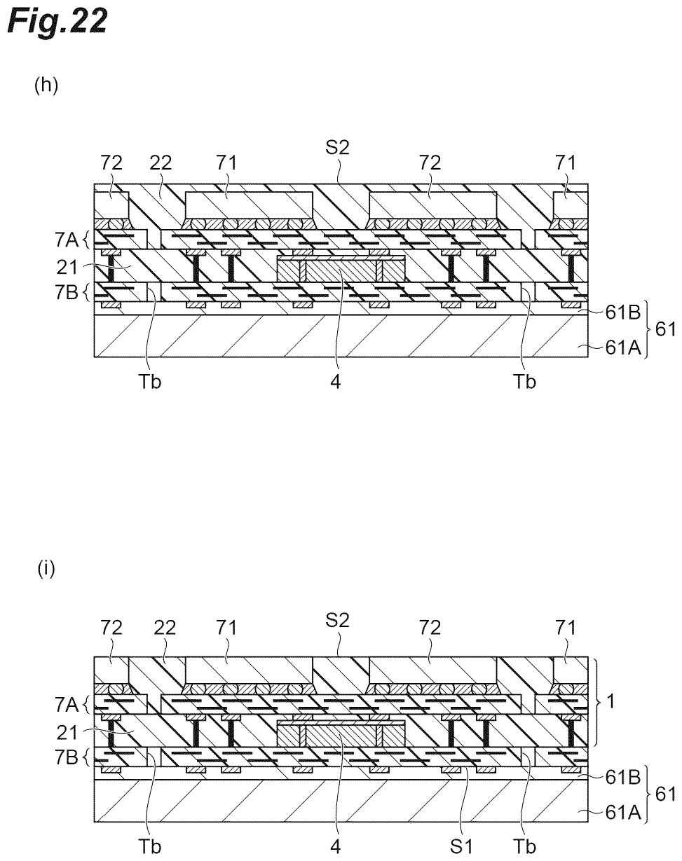

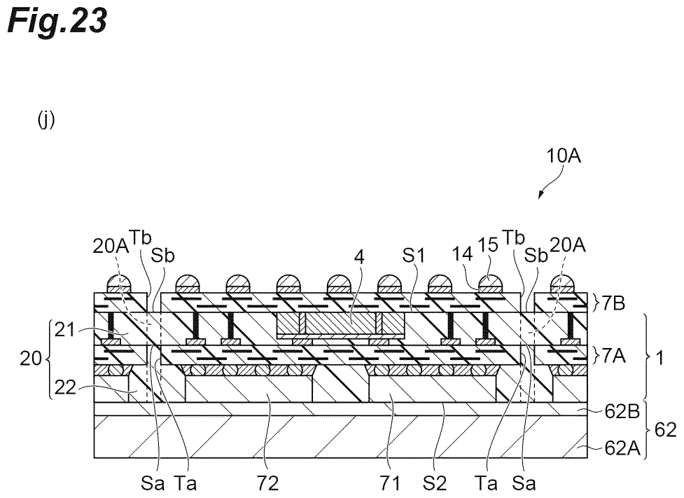

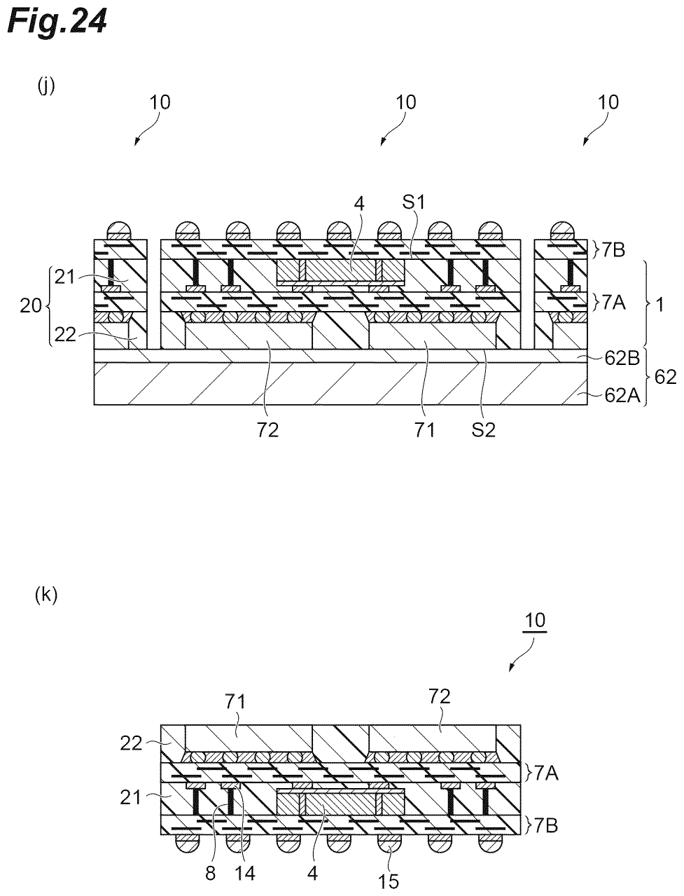

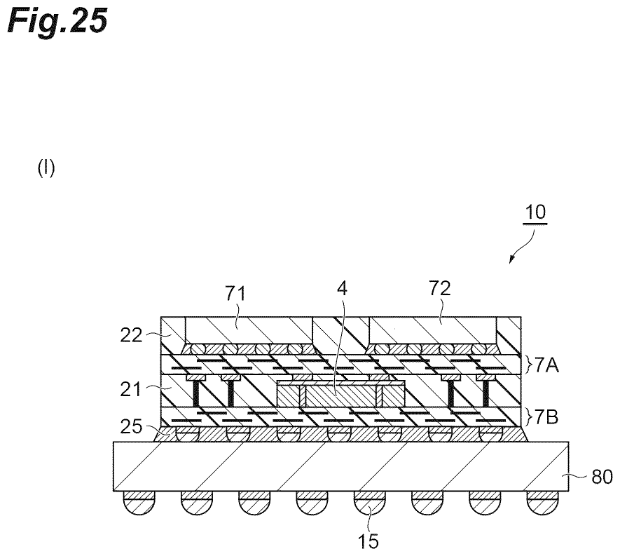

In the case of the method illustrated in FIGS. 19 to 25, the intermediate structure 10A is prepared in a way that includes temporarily fixing the plurality of relay wiring portions 4 on the carrier substrate 60 (FIG. 19(a)); forming the first sealing resin layer 21 used for sealing the relay wiring portion 4 on the carrier substrate 60 (FIG. 19(b)); forming the trench Tb having the bottom surface Sb on which the first sealing resin layer 21 is exposed on the side of the relay wiring portions 4 and the first sealing resin layer 21 opposite to the carrier substrate 60; forming the redistribution layer 7B having the electrode 14 provided on the side opposite to the relay wiring portions 4 (FIG. 20(d)); separating the carrier substrate 60 from the relay wiring portion 4 and the first sealing resin layer 21 to expose the relay wiring portion 4 and the first sealing resin layer 21 (FIG. 20(e)); forming the internal redistribution layer 7A, which has the internal trench Ta with the bottom surface Sa that exposes the first sealing resin layer 21 is formed, on the side of the relay wiring portion 4 and the first sealing resin layer 21 opposite to the redistribution layer 7B (FIG. 21(f)); arranging the plurality of semiconductor components 71 and 72 on the side of the internal redistribution layer 7A opposite to the relay wiring portion 4 (FIG. 21(g)), forming the second sealing resin layer 22 that seals the semiconductor components 71 and 72 and fills the internal trench Ta, on the internal redistribution layer 7A (FIG. 22(h)); after separating the carrier substrate 61 from the base material 1 and the redistribution layer 7B, temporarily fixing the base material 1 and the redistribution layer 7B onto another carrier substrate 62 in an orientation in which the second main surface S2 is positioned on the side of the carrier substrate 62 (FIG. 23(j)); and providing the bump 15 on the electrode 14 of the redistribution layer 7B (FIG. 23(j)). Then, as illustrated in FIGS. 24 and 25, the base material 1 (resin portion 20) is cut along the trenches Tb and the internal trenches Ta at the position of the through portion 20A, obtaining the wiring structure 10 (semiconductor package).

The first sealing resin layer 21 is a plate-shaped resin molded body having the first main surface S1. Before the redistribution layer 7B is formed, as illustrated in FIG. 19(c), a part of the first sealing resin layer 21 may be removed from the first main surface SI to form a surface that exposes the relay wiring portion 4 and the copper pillar 8. The second scaling resin layer 22 is a plate-shaped resin molded body having a second main surface S2. Before the redistribution layer 7B is formed, as illustrated in FIG. 22(i), a part of the second sealing resin layer 22 may be removed from the side opposite to the carrier substrate 60 to form a surface that exposes the semiconductor components 71 and 72.

The resin portion 20 (the first sealing resin layer 21 and the second sealing resin layer 22) may contain resin and an inorganic filler. The insulating resin layer in the redistribution layer 7B may also contain an inorganic filler. The internal insulating resin layer in the internal redistribution layer 7A may also contain an inorganic filler. In the insulating resin layer of the redistribution layer 7B, the internal insulating resin layer of the internal redistribution layer 7A, or both, the ratio of the volume of the inorganic filler to the volume of each layer may be smaller than the ratio of the volume of the inorganic filler contained in the resin portion to the volume of the resin portion. In the case where the ratio of the inorganic filler is different in the first sealing resin layer 21 and the second sealing resin layer 22, the ratio of the volume of the inorganic filler in the insulating resin layer of the redistribution layer 7B or the internal insulating resin layer of the internal redistribution layer 7A may be smaller than the smallest ratio of the volume of the inorganic filler in each layer.

The ratio of the volume of the inorganic filler in the first sealing resin layer 21 and the second sealing resin layer 22 to the volume of each layer may be, for example, 10% or more and 95% or less by volume. The ratio of the volume of the inorganic filler in the insulating resin layer of the redistribution layer 7B and the internal insulating resin layer of the internal redistribution layer 7A to the volume of the insulating resin layer may be, for example, 0% or more and 50% or less by volume.

### REFERENCE SIGNS LIST

1 base material
3 insulating resin layer
5 wiring
3a, 3b, 3c pattern layer
4 relay wiring portion
5a, 5b, 5c conductor layer
7, 7B wiring layer (redistribution layer)
7A internal wiring layer (internal redistribution layer)
10 wiring structure (semiconductor package)
10A intermediate structure
20 resin portion
20A through portion
30 resin layer
35 opening for wiring
37 opening for trench
40 semiconductor chip
42 terminal
43 integrated circuit
44 conductive via
51 via portion
52 wiring pattern portion
60, 61, 62 carrier substrate
71, 72 semiconductor component
80 organic wiring substrate
100 electronic component device
S1 first main surface of base material
S2 second main surface of base material
S4 main surface of semiconductor chip including integrated circuit
T, Tb trench
Ta internal trench

1. A method for manufacturing a semiconductor package, comprising:
preparing an intermediate structure comprising a base material and a redistribution layer, the base material having a first main surface and a second main surface on a rear side of the first main surface, the redistribution layer being provided on the first main surface and comprising an insulating resin layer and wiring provided in the insulating resin layer, the base material comprising a resin portion comprising a through portion penetrating from the first main surface to the second main surface, the redistribution layer forming a trench having a bottom surface on which the through portion is exposed; and
cutting the through portion along the trench, thereby forming a plurality of wiring structures, each comprising the divided base material and the redistribution layer provided on the base material,
wherein the base material comprises
an internal redistribution layer provided inside the first main surface and the second main surface, and comprising an internal insulating resin layer and wiring provided in the internal insulating resin layer;
a plurality of relay wiring portions provided on a side of the internal redistribution layer facing the first main surface and connected to the wiring of the internal redistribution layer;
a first sealing resin layer that seals the relay wiring portion on the internal redistribution layer;
a plurality of semiconductor components provided on a side of the internal redistribution layer facing the second main surface and connected to the wiring of the internal redistribution layer; and
a second sealing resin layer that seals the semiconductor component on the internal redistribution layer,
wherein the internal redistribution layer forms an internal trench having a bottom surface on which the first sealing resin layer is exposed,
the second sealing resin layer fills the internal trench,
the bottom surface of the trench and the bottom surface of the internal trench overlap as viewed from a thickness direction of the base material,
the resin portion comprises the first sealing resin layer and the second sealing resin layer,
the through portion is cut along both the trench and the internal trench, and
the plurality of wiring structures being formed each comprises the relay wiring portion and the plurality of semiconductor components electrically connected via the relay wiring portion.

2. The method according to claim 1, wherein
the intermediate structure is prepared in a way that includes,
temporarily fixing the plurality of relay wiring portions on a carrier substrate;
forming the first sealing resin layer sealing the relay wiring portion on the carrier substrate;
forming the internal redistribution layer on a side of the relay wiring portion and the first sealing resin layer opposite to the carrier substrate, the redistribution layer forming the internal trench having a bottom surface on which the first sealing resin layer is exposed;
arranging the plurality of semiconductor components on a side of the internal redistribution layer opposite to the relay wiring portion;
forming the second sealing resin layer sealing the semiconductor component and filling the internal trench on the internal redistribution layer;
separating the carrier substrate from the relay wiring portion and the first sealing resin layer to expose the relay wiring portion and the first sealing resin layer; and
forming the redistribution layer on a side of the relay wiring portion and the first sealing resin layer opposite to the internal redistribution layer, the redistribution layer forming the trench having a bottom surface on which the first sealing resin layer is exposed.

3. The method according to claim 2, wherein
the relay wiring portion comprises a semiconductor chip having a main surface comprising an integrated circuit, and
the relay wiring portion is temporarily fixed onto the carrier substrate in an orientation in which the main surface comprising the integrated circuit is positioned on a side opposite to the carrier substrate.

4. The method according to claim 1, wherein
the intermediate structure is prepared in a way that includes,
temporarily fixing a plurality of the relay wiring portions on a carrier substrate;
forming the first sealing resin layer sealing the relay wiring portion on the carrier substrate;
forming the redistribution layer on a side of the relay wiring portion and the first sealing resin layer opposite to the carrier substrate, the redistribution layer forming the trench having a bottom surface on which the first sealing resin layer is exposed;
separating the carrier substrate from the relay wiring portion and the first sealing resin layer to expose the relay wiring portion and the first sealing resin layer;
forming the internal redistribution layer on a side of the relay wiring portion and the first sealing resin layer opposite to the redistribution layer, the internal redistribution layer having a bottom surface on which the first sealing resin layer is exposed;
arranging a plurality of the semiconductor components on a side of the internal redistribution layer opposite to the relay wiring portion; and
forming the second sealing resin layer sealing the semiconductor component and filling the internal trench on the internal redistribution layer.

5. The method according to claim 4, wherein
the relay wiring portion comprises a semiconductor chip having a main surface comprising an integrated circuit, and
the relay wiring portion is temporarily fixed onto the carrier substrate in an orientation in which the main surface comprising the integrated circuit is positioned to a side of the carrier substrate.

6. The method according to claim 1, wherein the resin portion comprises an inorganic filler.

7. The method according to claim 1, wherein
the insulating resin layer and the internal insulating resin layer do not comprise an inorganic filler, or the insulating resin layer and the internal insulating resin layer comprise the inorganic filler, and
in a case where the insulating resin layer and the internal insulating resin layer comprise the inorganic filler, a ratio of a volume of the inorganic filler comprised in the insulating resin layer to a volume of the insulating resin layer and a ratio of a volume of the inorganic filler comprised in the internal insulating resin layer to a volume of the internal insulating resin layer are smaller than a ratio of a volume of the inorganic filler comprised in the resin portion to a volume of the resin portion.

8. The method according to claim 1, further comprising:
repeating a process of forming a pattern layer through exposure and development of a photosensitive resin layer to form a plurality of pattern layers, each of the pattern layers having a pattern including an opening for the wiring and an opening for the trench, the plurality of the pattern layers forming a plurality of openings for the trench; and
repeating a process of forming a conductor layer comprising a via portion filling the opening for the wiring to form a plurality of conductor layers, wherein
at least one of the insulating resin layer of the redistribution layer or the internal insulation resin layer of the internal redistribution layer is formed by the plurality of the pattern layers,
the wiring of at least one of the redistribution layer or the internal redistribution layer is formed by the plurality of the conductor layers, and the trench is formed by connecting the plurality of the openings for the trench.

9. The method according to claim 1, further comprising:
repeating a process of forming a pattern layer by removing a part of a resin layer with laser irradiation to form a plurality of pattern layers, each of the pattern layers having a pattern including an opening for the wiring and an opening for the trench, the plurality of the pattern layers forming a plurality of openings for the trench; and
repeating a process of forming a conductor layer comprising a via portion filling the opening for the wiring to form a plurality of conductor layers, wherein
at least one of the insulating resin layer of the redistribution layer or the internal insulating resin layer of the internal redistribution layer is formed by the plurality of the pattern layers,
the wiring of at least one of the redistribution layer or the internal redistribution layer is formed by the plurality of the conductor layers, and
the trench is formed by connecting the plurality of the openings for the trench.

10. The method according to claim 1, further comprising:
repeating a process of forming a pattern layer through exposure and development of a photosensitive resin layer to form a plurality of pattern layers, each of the pattern layers having a pattern including an opening for the wiring; and
repeating a process of forming a conductor layer comprising a via portion filling the opening for the wiring to form a plurality of conductor layers, wherein
at least one of the insulating resin layer of the redistribution layer or the internal insulating resin layer of the internal redistribution layer is formed by the plurality of the pattern layers,
the wiring of at least one of the redistribution layer or the internal redistribution layer is formed by the plurality of the conductor layers, and
a part of the formed insulating resin layer or the internal insulating resin layer is removed with laser irradiation to form the trench.

11. The method according to claim 1, wherein the trench has a width increasing in a direction away from the base material.

12. The method according to claim 1. wherein the internal trench has a width increasing in a direction away from the first sealing resin laver.

13. The method according to claim 1, further comprising: mounting the wiring structure on an organic wiring substrate.
